(19) United States
(12) Patent Application Publication
(10) Pub. No.: US 2012/0186626 A1
(43) Pub. Date: Jul. 26, 2012

(54) SOLAR ENERGY COLLECTION SYSTEM

(75) Inventors: Supratik Guha, Chappaqua, NY (US); Yves C. Martin, Ossining, NY (US); Naim Moumen, Walden, NY (US); Robert L. Sandstrom, Chestnut Ridge, NY (US); Theodore G. Van Kessel, Millbrook, NY (US)

(73) Assignee: INTERNATIONAL BUSINESS MACHINES CORPORATION, Armonk, NY (US)

(21) Appl. No.: 13/014,319

(22) Filed: Jan. 26, 2011

(51) Int. Cl. H01L 31/052

(52) U.S. Cl. 136/246

(57) ABSTRACT

A solar energy collection system includes a reference member, a support member rotatably mounted relative to the reference member, and a drive system operatively coupled between the reference member and the support member. The drive system includes a linear actuator having a fixed portion operatively connected to the reference member and a strut portion that is selectivity extendable relative to the fixed portion. The strut portion includes an end section. A first connector member is operatively connected between the reference member and the end section of the strut portion, and a second connector member is operatively connected between the support member and the end section of the strut portion. Selective extension and retraction of the strut portion relative to the fixed portion selectively shifts the support member along a desired path.

### BACKGROUND

The present invention relates to the art of solar energy collection and, more particularly, to a drive system for a solar collector.

Solar power systems fall generally into two categories: fixed position flat panel systems, and tracking solar collection systems. Fixed position flat panel systems employ one or more stationary panels that are arranged in an area having an unobstructed view of the sun. As the earth rotates, the sun's rays move over the stationary panel(s) with varying degrees of intensity depending upon geographic location, the time of day and the time of the year. In contrast, tracking solar collection systems collect, and focus the sun's rays onto one or more solar collectors. Tracking solar collectors employ a tracking system that follows the sun's path in order to enhance energy collection. Simply put, fixed position flat panels represent a passive solar collection system, while tracking solar collector systems represent a more active energy collection system.

Tracking systems for solar collectors take on a variety of forms, from complex computer and satellite (GPS) tracking to the use of photodiodes. GPS tracking relies on determining a particular location on the ground, and correlating that location to the location of the sun at a given, known, time of day. More conventional systems utilize an auxiliary alignment sensor that employs photodiodes. The photodiodes rely on differential sensing parameters to track the sun. That is, one or more photodiode cells are exposed to the sun's rays. The sun's rays impinge upon the photodiodes and a controller determines how much, for example, voltage is produced by each photodiode cell. The controller then orients the plurality of photodiode cells until voltage from each cell is substantially similar. At this point, an offset is calculated and the solar collector is oriented to a desired orientation. The offset represents a distance between a solar collector and the photodiodes. The need to calculate an offset increases tracking complexity and reduces collection efficiency.

The tracking system shifts the solar collector using a drive system. In some cases, the drive system includes a complex arrangement of gears and drive shafts. In other arrangements, a powered mechanical strut is positioned to shift the solar collector into a desired alignment. Powered mechanical struts are limited by mechanical clearance angles. The mechanical clearance angles constrain the drive system to shifting the solar collector axis along a path that is less than 180°. Powered mechanical strut systems are also limited by highly non-linear translation. That is, both rotation and torque responses of the linear translation of the powered mechanical strut to creating a rotation of the solar collector are highly non-linear.

### SUMMARY

According to one exemplary embodiment, a solar energy collection system includes a reference member that establishes a mechanical reference point, a support member rotatably mounted relative to the reference member, and a drive system operatively coupled between the reference member and the support member. The drive system includes a linear actuator having a fixed portion operatively connected to the reference member and a strut portion that is selectivity extendable relative to the fixed portion. The strut portion includes an end section. A first connector member is operatively connected between the reference member and the end section of the strut portion, and a second connector member is operatively connected between the support member and the end section of the strut portion. Selective extension and retraction of the strut portion relative to the fixed portion selectively shifts the support member along a desired path.

According to another exemplary embodiment, a method of positioning a solar collector mounted to a support member includes shifting a strut portion relative to a fixed portion of a linear actuator. The fixed portion is coupled to a reference member that establishes a mechanical reference point. The method further includes pivoting a first connector member positioned between a first end section of the strut portion and the reference member, and pivoting a second connector member positioned between the first end section of the strut portion and the support member. The method also includes rotating the support member moveably mounted to the reference member from a first position to a second position.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which:

FIG. 1 is a plan view of a solar energy collection system in accordance with an exemplary embodiment;

FIG. 2 is a plan view of a solar collector of the solar energy collection system illustrated in a first position;

FIG. 3 is a plan view of the solar energy collection system illustrating the solar collector of FIG. 2 shifted by a drive system in accordance with the exemplary embodiment from the first position to a second position;

FIG. 4 is a plan view of the solar energy collection drive system illustrating the solar collector of FIG. 3 shifted by the drive system in accordance with the exemplary embodiment from the second position to a third position;

FIG. 5 is a plan view of the solar energy collection system illustrating the solar collector of FIG. 4 shifted by the drive system in accordance with the exemplary embodiment from the third position to a fourth position; and

FIG. 6 is a plan view of the solar energy collection system illustrating the solar collector of FIG. 5 shifted by the drive system in accordance with the exemplary embodiment from the fourth position to a fifth position.

### DETAILED DESCRIPTION

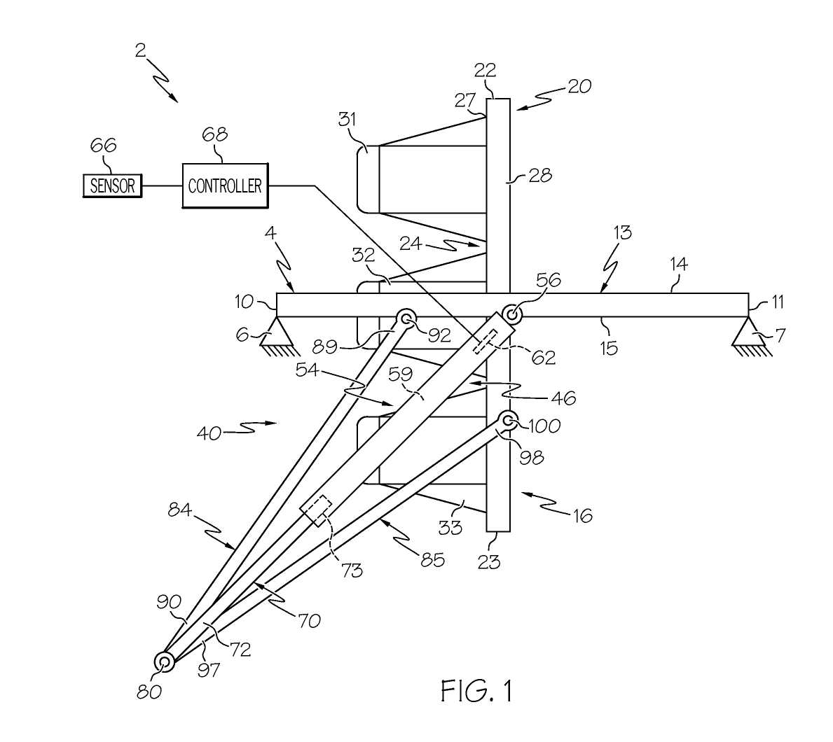

With reference now to FIG. 1, a solar energy collection system in accordance with an exemplary embodiment is indicated generally at 2. Solar energy collection system 2 includes a reference member 4 that establishes a mechanical reference point. In the exemplary embodiment shown, reference member 4 is mounted relative to one or more fixed reference points indicated schematically at 6 and 7. However, it should be understood, that reference member 4 itself need not be fixed. In the exemplary embodiment shown, reference member 4 includes a first end 10 that extends to a second end 11 through an intermediate portion 13. Intermediate portion 13 includes a first surface 14 and an opposing second surface 15. A solar collector or concentrator support member 16 is moveably mounted to reference member 4. Support member 16 includes a main body 20 having a first end section 22 that extends to a second end section 23 through an intermediate section 24. Intermediate section 24 includes a first surface 27 and an opposing second surface 28. A plurality of solar concentrators/collectors 31-33 are mounted to first surface 27. Solar collectors 31-33 convert solar energy from the sun to electrical energy and can take on a variety of forms ranging from simple flat panels to more complex solar concentrators. In order to enhance energy conversion, solar collectors 31-33 are moved along an arcuate path to track the sun's position. Solar collectors 31-33 are moved by a drive system 40 which, as will be discussed more fully below, is mounted between reference member 4 and support member 16.

In accordance with an exemplary embodiment, drive system 40 includes a linear actuator 46 having a fixed portion 54. Fixed portion 54 includes a first end portion 56 that is pivotally mounted to reference member 4. First end portion 56 extends to a second end portion 57 through a hollow interior 59 that houses a drive component 62. Drive component 62 is operatively connected to a controller 68. Controller 68 selectively activates drive component 62 to position support member 16. In order to refine positioning of support member 16, controller 68 includes a position sensor 66. Position sensor 66 provides feedback and/or feedforward control to aid in providing a high degree of precision for positioning support member 16. Position sensor 66 can take a variety of forms including servos, gravitometers, magnetometers, optical sensors, Hall effect sensors, resistance sensors, and/or other forms of position sensing elements. In accordance with one aspect of the exemplary embodiment, drive component 62 comprises an electric motor. In accordance with another aspect of the exemplary embodiment, drive component 62 comprises a pneumatic piston. In accordance with yet another aspect of the exemplary embodiment, drive component 62 comprises a hydraulic piston. In accordance with still another aspect of the exemplary embodiment, drive component 62 comprises a piezo-electric inchworm. At this point it should be clear that the particular type of drive component 62 can vary. Drive component 62 is configured to shift a strut portion 70 relative to fixed portion 54

Strut portion 70 includes a first end section 72 that extends to a second end section 73 that is arranged within hollow interior 59. Strut portion 70 is configured to shift within hollow interior 59 relative to fixed portion 54. Strut portion 70 also includes a pivot joint 80 arranged at first end section 72. Drive system 40 is also shown to include a first connector member 84 and a second connector member 85. First and second connector members 84 and 85 can be formed from a variety of materials including various metals such as titanium, aluminum, magnesium, steel, copper and/or alloys thereof, or composites including various plastics and/or carbon fiber arrangements. In accordance with one aspect of the exemplary embodiment, first and second connector members 84 and 85 are formed from a lightweight material that may be readily dynamically stabilized yet also provides a desired stiffness. First connector member 84 includes a first end 89 that extends to a second end 90. First end 89 of first connector member 84 is pivotally connected to reference member 4 through a pivot joint member 92. Second end 90 of first connector member 84 is pivotally connected to pivot joint 80 provided on strut portion 70. Similarly, second connector member 85 includes a first end 97 that extends to a second end 98. First end 97 of second connector member 85 is pivotally connected to support member 16 through a pivot joint component 100. Second end 98 of second connector member 85 is pivotally connected to pivot joint 80 provided on strut portion 70. At this point it should be understood that while shown as ball joints, pivot joint 80, pivot joint member 92, and pivot joint component 100 can take on a variety of forms including universal joints, and simple hinge joints.

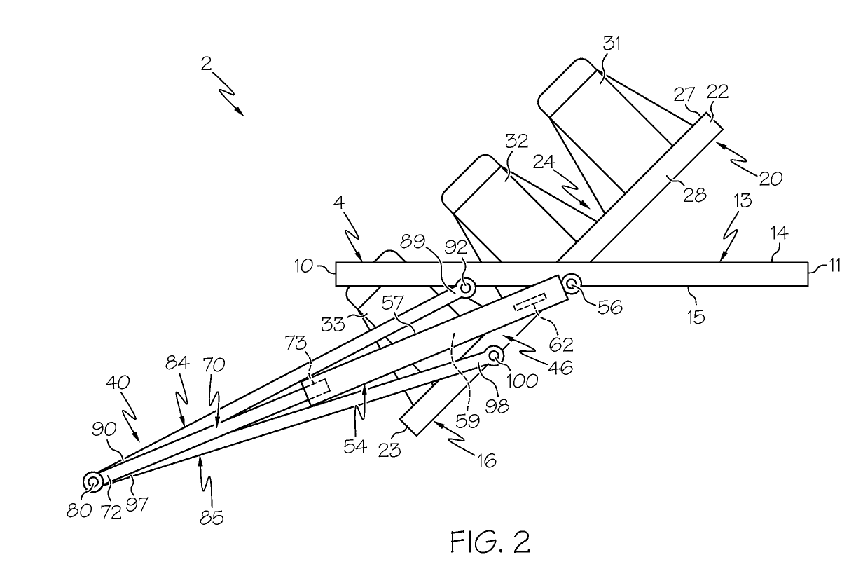

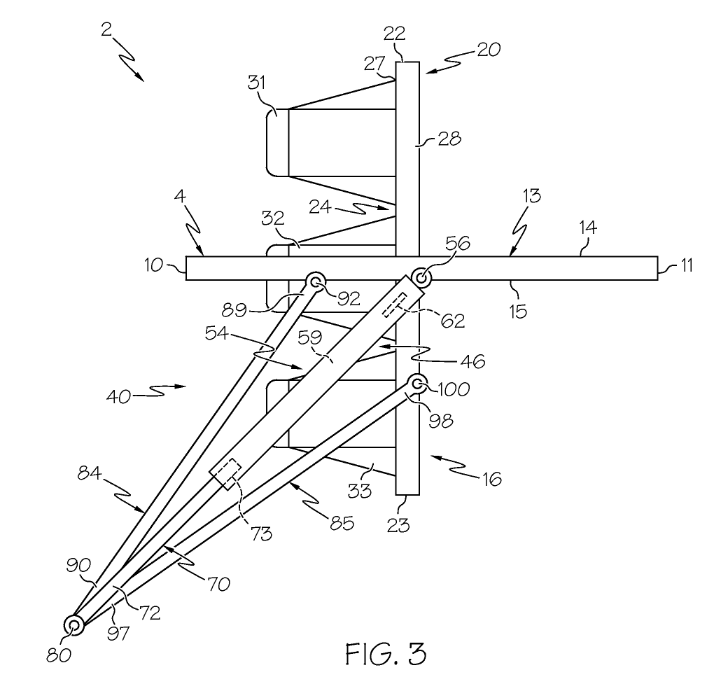

With this arrangement, when strut potion 70 is fully extended, a force is applied to first and second connector members 84 and 85 that results in a translation of support member 16 to a first position such as shown in FIG. 2. In the first position, a first acute angle is formed between first surface 27 of support member 16 and first surface 14 of reference member 4. As strut portion 70 is retracted into hollow interior 59, forces applied to first and second connector members 84 and 85 create impart a rotation to support member 16. In the exemplary embodiment shown, support member 16 shifts from the first position to a second position such as shown in FIG. 3. In the second position, support member 16 is substantially perpendicular to reference member 4.

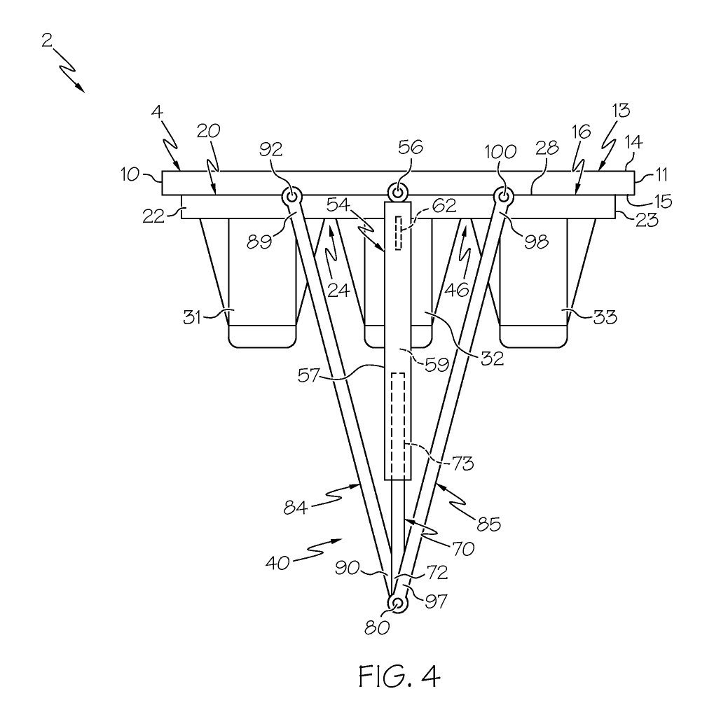

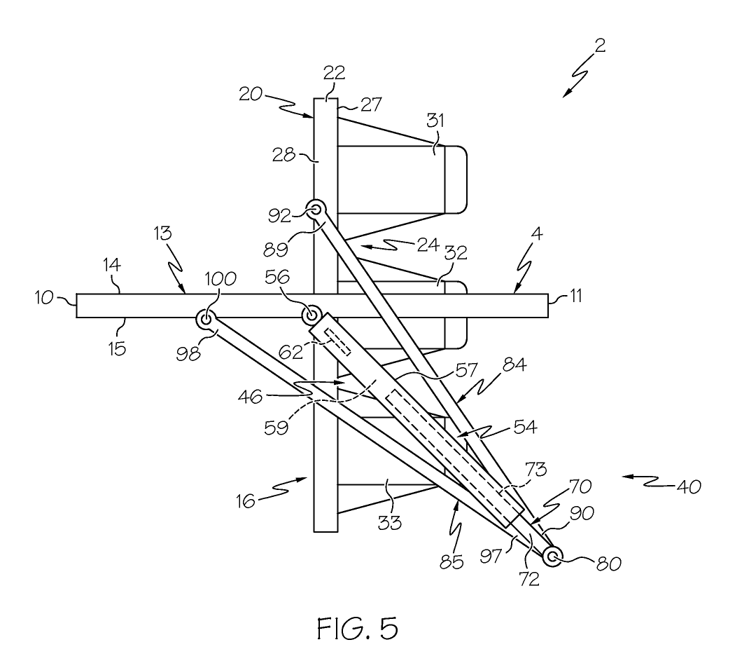

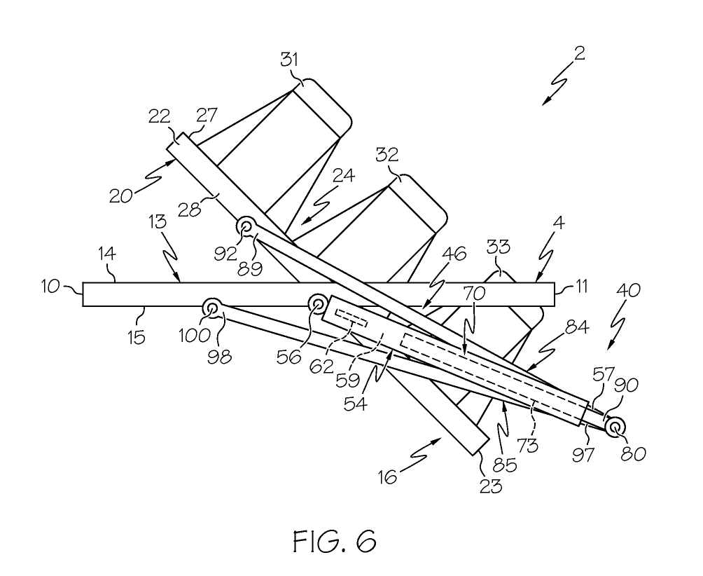

Continued retraction of strut portion 70 applies force to first and second connector members 84 and 84 that results in continues rotation of support member 16 to a third position such as illustrated in FIG. 4. In the third position, support member 16 is substantially parallel to reference member 4. As strut portion 70 continues to retract, forces applied to first and second connector members 84 and 85 create still further rotation of support member 16 to a fourth position such as shown in FIG. 5. In the fourth position, support member 16 is substantially perpendicular to reference member 4 with solar collectors 31-33 facing in a direction that is 180° from that established in the second position. Full retraction of strut member 70 imparts a force to first and second connector members 84 and 85 that rotates support member 16 into a fifth position such a shown in FIG. 6. In the fifth position, a second acute angle is formed between first surface 27 of support member 16 and first surface 14 of reference member 4. The second acute angle is 180° relative to the first acute angle.

At this point it should be understood that the exemplary embodiments provide a system for shifting solar collectors in one axis into alignment with solar rays. Of course, it should be understood, that the exemplary embodiments can be configured to shift solar collectors in multiple axes into alignment with solar rays. The drive system of the exemplary embodiments employs a linear actuator that is configured to shift a support member through an arc that is greater than 180° with enhanced linearity, high mechanical precision and mechanical stiffness and low cost. In addition, it should be understood that by varying the length of the connector members an/or the various connection points between the connector members and the reference member and support member, a range of translatable rotation may be established that approaches 360°. It should be further understood that the above described arrangement provides a light weight structure that can be readily dynamically stabilized yet provides the desired stiffness that leads to high precision placement. Finally it should be understood that the first through fifth positions described above are exemplary.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated

While the preferred embodiment to the invention had been described, it will be understood that those skilled in the art, both now and in the future, may make various improvements and enhancements which fall within the scope of the claims which follow. These claims should be construed to maintain the proper protection for the invention first described.

What is claimed is:

1. A solar energy collection system comprising:
a reference member that establishes a mechanical reference point;
a support member rotatably mounted relative to the reference member; and
a drive system operatively coupled between the reference member and the support member, the drive system including:
a linear actuator having a fixed portion operatively connected to the reference member and a strut portion that is selectivity extendable relative to the fixed portion, the strut portion including an end section;
a first connector member operatively connected between the reference member and the end section of the strut portion; and
a second connector member operatively connected between the support member and the end section of the strut portion, wherein selective extension and retraction of the strut portion relative to the fixed portion selectively shifts the support member along a desired path.

2. The solar energy collection system according to claim 1, wherein the first connector member is a rigid member having a fixed length.

3. The solar energy collection system according to claim 1, wherein the second connector member is a rigid member having a fixed length.

4. The solar energy collection system according to claim 1, wherein the end section of the strut portion includes a pivot joint.

5. The solar energy collection system according to claim 4, wherein the first connector member includes a first end that extends to a second end, the first end of the first connector member being connected to the reference member through a pivot joint member and the second end of the first connector member being connected to the pivot joint of the strut portion.

6. The solar energy collection system according to claim 5, wherein the second connector member includes a first end and a second end, the first end of the second connector member being connected to the support member through a pivot joint component and the second end of the second connector member being connected to the pivot joint of the strut portion.

7. The solar energy collection system according to claim 6, wherein each of the pivot joint, pivot joint member and pivot joint component comprise ball joints.

8. The solar energy collection system according to claim 1, further comprising: a drive component that is selectively activated to extend and retract the strut portion relative to the fixed portion.

9. The solar energy collection system according to claim 8, wherein drive component is an electric motor.

10. The solar energy collection system according to claim 8, wherein the drive component is a pneumatic piston.

11. The solar energy collection system according to claim 8, wherein the drive component is a hydraulic piston.

12. The solar energy collection system according to claim 8, wherein the drive component is a piezo-electric inchworm.

13. The solar energy collection system according to claim 1, further comprising: a solar collector mounted to the support member.

14. The solar energy collection system according to claim 1, further comprising: a controller operatively connected to the drive system, the controller being configured and disposed to shift actuate the linear actuator.

15. The solar energy collection system according to claim 14, further comprising: a position sensor operatively connected to the controller, the position sensor facilitating one of a feedback and feedforward control for establishing a desired position of the support member.

16. A method of positioning a solar collector mounted to a support member, the method comprising:
shifting a strut portion relative to a fixed portion of a linear actuator, the fixed portion being coupled to a reference member that establishes a mechanical reference point;
pivoting a first connector member positioned between a first end section of the strut portion and the reference member;
pivoting a second connector member positioned between the first end section of the strut portion and the support member; and
rotating the support member moveably mounted to the reference member from a first position to a second position.

17. The method of claim 16, wherein shifting the strut portion relative to the fixed portion includes activating a drive component operatively coupled to the strut portion.

18. The method of claim 17, wherein activating the drive component comprises activating an electric motor operatively coupled to the strut portion.

19. The method of claim 17, wherein activating the drive component comprises shifting a pneumatic piston operatively coupled to the strut portion.

20. The method of claim 17, wherein activating the drive component comprises shifting a hydraulic piston operatively coupled to the strut portion.
